(19) United States
(12) Patent Application Publication
(10) Pub. No.: US 2022/0377944 A1
(43) Pub. Date: Nov. 24, 2022

(54) COOLING SYSTEM, AIR REMOVAL ATTACHMENT, AIR REMOVAL METHOD, AND STORAGE MEDIUM

(71) Applicant: NEC Corporation, Minato-ku, Tokyo (JP)

(72) Inventors: Nirmal Singh RAJPUT, Tokyo (JP); Masaki CHIBA, Tokyo (JP); Mahiro HACHIYA, Tokyo (JP); Takafumi NATSUMEDA, Tokyo (JP); Yoshinori MIYAMOTO, Tokyo (JP); Minoru YOSHIKAWA, Tokyo (JP)

(73) Assignee: NEC Corporation, Minato-ku, Tokyo (JP)

(21) Appl. No.: 17/764,293

(22) PCT Filed: Oct. 2, 2019
(86) PCT No.: PCT/JP2019/039729

§ 371 Date: Mar. 28, 2022

(51) Int. Cl. H05K 7/20; F28D 15/06; F28D 15/02

(52) U.S. Cl. CPC H05K 7/20827; H05K 7/20381; F28D 15/06; F28D 15/0266

(57) ABSTRACT

The present invention provides an attachment for a server rack cooling system having at least one heat exchange condenser, the attachment includes: a pipe extension configured to connect to a portion of the server rack cooling system at which air and refrigerant are able to be transferred into the attachment from the at least one heat exchange condenser; a valve on the pipe extension configured to allow exhaust to the outside through the pipe extension at an open position and to block exhaust to the outside at a closed position; and an sensor disposed at a position inside of the pipe extension between the at least one heat exchange condenser and the valve and configured to provide a detection signal determined by a presence of fluid at the position of the sensor; wherein, the valve is opened and closed based on the detection signal from the sensor.

### TECHNICAL FIELD

The present disclosure relates to a cooling system, an air removal attachment, an air removal method to remove air from a cooling system, and a storage medium storing instructions for implementing the air removal method by a computer or similar control device. Specifically, the disclosed invention detects and removes air from vapor compression cycle in which part or all of a cycle operates below atmospheric pressure.

### BACKGROUND

Vapor compression cycle cooling systems are employed in data centers to provide a constant supply of cold air, which in turn is utilized to cool servers. Usually, vapor compression cycle systems operate above atmospheric pressure. When low pressure refrigerant is utilized in the vapor compression cycle, some components such as the evaporator, can operate below atmospheric pressure.

Vapor compression cycle cooling systems are designed with a permissible leakage rate. In vapor compression cycle systems which operate above atmospheric pressure, due to leakage, refrigerant keeps leaking to outside environment and a maintenance is required to restore refrigerant level to maintain normal operation. In vapor compression cycle systems, which operates below atmospheric pressure or in which a component operates below atmospheric pressure, in addition of refrigerant leak to outside environment, an extra problem, which is air leak into system occurs.

Air leaking into the system usually collects over time at some components such as the condenser, and reduces its performance over time. Therefore, additional maintenance for air removal is required in vapor compression cycle wherein a component or whole system operates below atmospheric pressure.

### REFERENCES

### [Patent Document 1]

US Patent, US2012-180797A1

### [Patent Document 2]

Japanese Patent, JPS6092846U

### Technical Problem

When air gets collected in vapor compression system, it reduces its performance. Therefore, air should be removed, at adequate time intervals by maintenance person or automatically, from vapor compression system.

### Proposed Solution

A first aspect of the present disclosure provides an attachment for a server rack cooling system having at least one heat exchange condenser, the attachment includes: a pipe extension configured to connect to a portion of the server rack cooling system at which air and refrigerant are able to be transferred into the attachment from the at least one heat exchange condenser; a valve on the pipe extension configured to allow exhaust to the outside through the pipe extension at an open position and to block exhaust to the outside at a closed position; and an sensor disposed at a position inside of the pipe extension between the at least one heat exchange condenser and the valve and configured to provide a detection signal determined by a presence of fluid at the position of the sensor; wherein, the valve is opened and closed based on the detection signal from the sensor.

A second aspect of the present disclosure provides an air removal method of an attachment for a server rack cooling system having at least one heat exchange condenser, the air removal method including: detecting a presence of a fluid at a position along an exhaust flow path of the attachment, and exhausting air from the attachment by opening a valve along the exhaust flow path based on the detection of the presence of the fluid, and blocking the exhaust of air by closing the valve in absence of the detection of the presence of the fluid.

A third aspect of the present disclosure provides a non-transitory computer readable storage medium storing instructions to cause a computer to perform the steps of: detecting a presence of a fluid at a position along an exhaust flow path of the attachment, and exhausting air from the attachment by opening a valve along the exhaust flow path based on the detection of the presence of the fluid, and blocking the exhaust of air by closing the valve in absence of the detection of the presence of the fluid.

A fourth aspect of the present disclosure provides a server rack cooling system including: a server rack; an evaporator configured to remove heat generated by the server rack by way of a refrigerant flown through the evaporator and configured to maintain a lower pressure than the outside air pressure; at least one heat exchange condenser configured to cool the refrigerant and into which refrigerant from the evaporator is flown; a pipe extension which connects to the at least one heat exchange condenser; a valve on the pipe extension configured to allow exhaust to the outside through the pipe extension at an open position and to block exhaust to the outside at a closed position; and a sensor disposed at a position inside of the pipe extension between the at least one heat exchange condenser and the valve and configured to provide a detection signal determined by a presence of fluid at the position of the sensor, wherein, the valve is opened and closed based on the detection signal from the sensor.

### BRIEF DESCRIPTION OF DRAWINGS

FIG. 1 shows a vapor compression system including an air removal system installed thereon.

FIG. 2 shows one of the embodiment of air removal system.

FIG. 3 shows one of the embodiment of air removal system.

FIG. 4 is a flow chart illustrating an operation of a first example embodiment of the present air removal system.

FIG. 5 is a flow chart illustrating an operation of a second example embodiment of the present air removal system.

FIG. 6 is a flow chart illustrating an operation of a third example embodiment of the present air removal system.

FIG. 7 is a flow chart illustrating an operation of a fourth example embodiment of the present air removal system.

FIG. 8 illustrates an embodiment of the present invention where the air removal system is an attachment to a cooling system at a heat exchange condenser of the cooling system.

FIG. 9 illustrates the basic hardware structure of a control unit device for performing the operations of the present disclosure.

### DETAILED DESCRIPTION

The vapor compression cooling system performance deterioration due to presence of air inside a cooling system is a known problem for low-pressure cooling system (see Patent Document 1). To avoid system performance deterioration, Patent Document 2 utilizes a structure similar to tank at top of condenser. Patent Document 2 describes natural cooling cycle to cool chips such as a CPU. During operation, part of the presently disclosed cooling system pressure is less than atmospheric pressure. Due to negative pressure, air enters into the cooling system. This leaked-in air usually flows with refrigerant to a higher location in the cooling system. As air is less dense than refrigerant vapor, the air gets stuck at higher parts of cooling system, i.e. condenser. The tank at the top of the condenser stores the air and solves the system performance deterioration problem. However, since the tank is of limited size, air will fill tank over time and after that air will start affecting condenser performance by reduction of the effective condensation area. This problem can be solved by utilizing disclosed invention.

Furthermore, by maintaining a negative pressure at the evaporator side of the cooling system and removing leaked-in air, it can be ensured that refrigerant leakage at the evaporator is unlikely to occur, and therefore, the evaporator can be disposed closer to the server rack without concern that such leaked refrigerant will damage components of the server rack. In conventional cooling systems, disposing the evaporator at a distance of about 300 cm or more may be necessary to prevent such damage from refrigerant leakage, however, this would not be necessary for a cooling system designed in accordance with the present disclosure.

### Detailed Description of First Example Embodiment

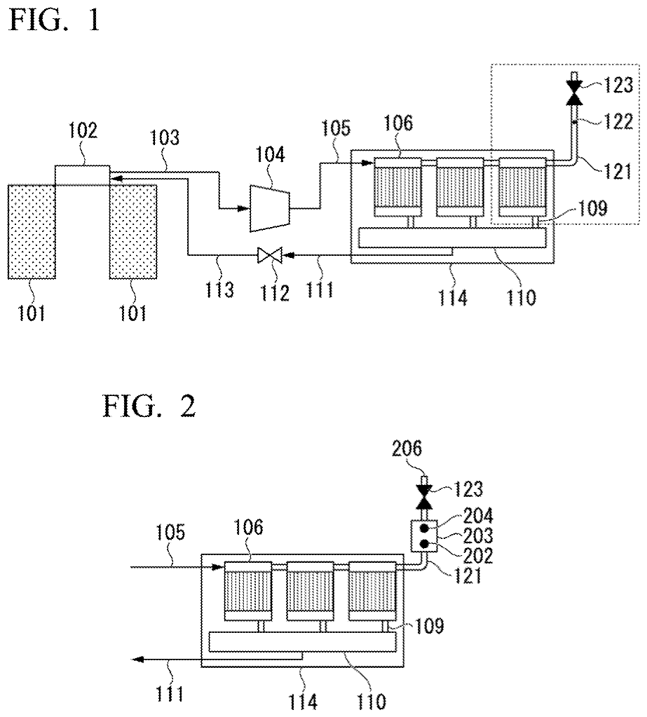

The present invention is explained with application to a vapor compression system as shown in FIG. 1, however, is not limited to vapor compression system. The vapor compression cycle includes an evaporator 102, which receives heat from a rack 101. The evaporator 102 transfers heat to a compressor 104 via a pipe 103. The compressor 104, transfers heat to a condenser 114 by a pipe 105. The condenser may include one or more heat exchangers 106. The heat exchangers 106 remove heat from the vapor compression system to the environment. The cooled refrigerant, coming from a pipe 109 collects in a tank 110. The stored refrigerant is transferred back to the evaporator 102 via a pipe 113, a pipe 111, and an expansion valve 112. The presently disclosed air removal system utilizes a pipe extension 121 from at least one of the heat exchangers 106 of the condenser 114. The pipe extension 121 contains an air sensor 122 and a valve 123. The air sensor 122 may include a sensor which can detect atmospheric air generally or any single component thereof such as a nitrogen sensor, an oxygen sensor, a carbon-dioxide sensor, or the like. Since the component gases of atmospheric air are not present in the refrigerant, air presence or absence can be detected by sensors specific to any of the component gases. The evaporator 102 is usually maintained at a pressure lower than atmospheric pressure in low pressure vapor compression systems. The air enters into the cooling system from the evaporator 102 and passes to the condenser 114 via a compressor 104 and the pipes 103, 105. The air in the condenser 114 gets collected at the top portion of the heat exchangers 106 because air density is lighter than refrigerant vapor density and air can't be condensed as at refrigerant vapor condensation thermo-physical conditions. Since, refrigerant flow is from the pipe 105 side of the heat exchangers 106 toward the pipe extension 121 side of the heat exchangers 106, air usually starts to collect at the heat exchanger 106 closest to the pipe extension 121. Since air is lighter, air passes toward a valve 123 of pipe extension 121. The air sensor 122, preferably placed toward refrigerant side, detects the air and provides a signal for valve 123 opening. As air is expelled from the system due to higher pressure in the condenser 114 than the atmosphere, the refrigerant rises up to the air sensor 122. When the air can't be detected by the air sensor 122, it sends a signal to close the valve 123. This control process is explained below according to the flow chart shown in FIG. 4 and related to the configuration illustrated in FIG. 1.

In Step S1, the air removal system determines if user stop command has been received or not. If not, then air removal system proceeds to S2, else air removal system stops.

In Step S2, the air sensor 122 disposed inside the pipe extension 121 detects if any air is present inside the pipe extension 121. If the air sensor 122 detects air, then air removal system proceeds to S3, else to Step S4.

In Step S3, if air is detected by the air sensor 122, then the valve 123 opens to expel the air out of the cooling system.

In Step S4, if air is not detected by the air sensor 122, i.e. air is absent, then the valve 123 closes to prevent any refrigerant from leaking to the outside environment.

### Detailed Description of Other Embodiments

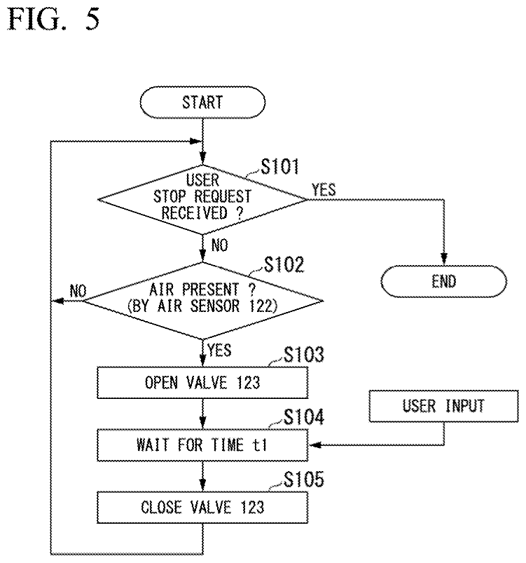

In one of the embodiment, air removal system includes a pipe extension 121, air sensor 122 and valve 123. The method for air removal system operation in this example embodiment is explained in explained below according to the flow chart shown in FIG. 5 and related to the configuration illustrated in FIG. 1

In Step S101, the air removal system determines if a user stop command has been received or not. If not, then the air removal system proceeds to S102, else the air removal system stops.

In Step S102, the air sensor 122 placed inside pipe extension 121 detects if any air is present inside the pipe extension 121. If air sensor 122 detects air, then air removal system proceeds to S103, else operation returns to Step S101.

In Step S103, if air is detected by air sensor 122, then valve 123 opens to expel the air out of the cooling system.

In Step S104, the air removal system waits for a predetermined time t1. During the time t1, the valve 123 remains open and due to a pressure difference between the condenser 114 and the outside environment, air is expelled out of the cooling system. The time t1 is user input and can be changed as per design requirements and specifications.

In Step S105, the air removal system closes the valve 123.

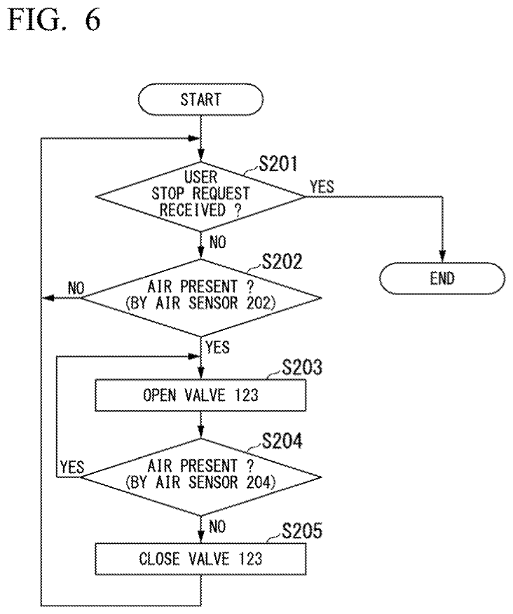

In another of the example embodiments, the air removal system includes the pipe extension 121, a tank 203 including a first air sensor 202 and a second air sensor 204, exhaust pipe 206, and valve 123. The method for air removal system operation in this example embodiment is explained in explained below according to the flow chart shown in FIG. 6 and related to the configuration illustrated in FIG. 2

In Step S201, the air removal system determines if a user stop command has been received or not. If not, then air removal system proceeds to S202, else the air removal system stops.

In Step S202, the first air sensor 202 placed inside tank 203 checks if any air is present inside the tank 203. If the first air sensor 202 detects air, then air removal system proceeds to S203, else returns to Step S201.

The physical significance of air detection by the first sensor 202 comes from the fact that the density of air is smaller than the refrigerant vapor density. When the air enters the inside of the tank 203 from the pipe extension 201, the air moves to the top part of the tank 203. Therefore, air detection by the first air sensor 202 signifies that tank 203 is completely filled with air.

In Step S203, if air is detected by the first air sensor 202, then the valve 123 opens to expel the air out from the cooling system. When the valve 123 opens, due to a pressure difference between the condenser 114 and the outside environment, the air is expelled from the cooling system to the outside environment via the exhaust pipe 206.

In Step S204, the second air sensor 204 disposed inside the tank 203 determines if any air is present in the tank 203. If the second air sensor 204 does not detect the presence of air, signifying that all air has been expelled from the cooling system to the outside environment, then the air removal system proceeds to S205 which results in a continuous open state of the valve 123.

In Step S205, the air removal system closes the valve 123.

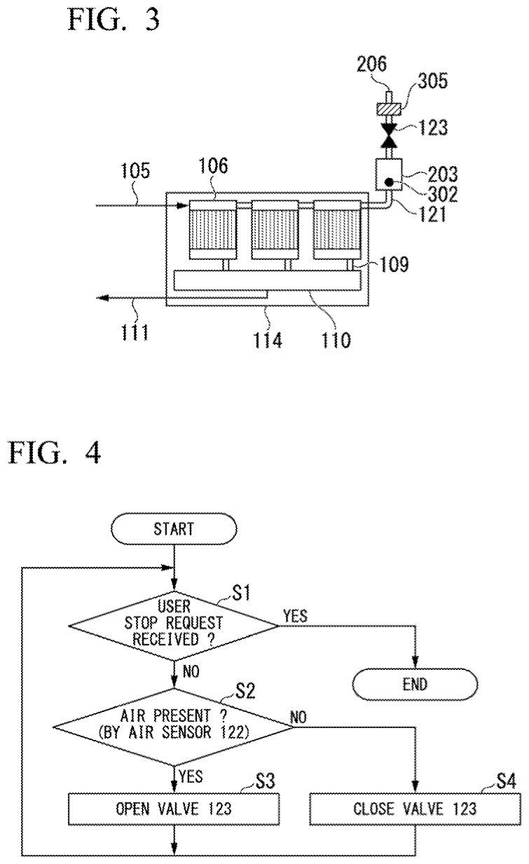

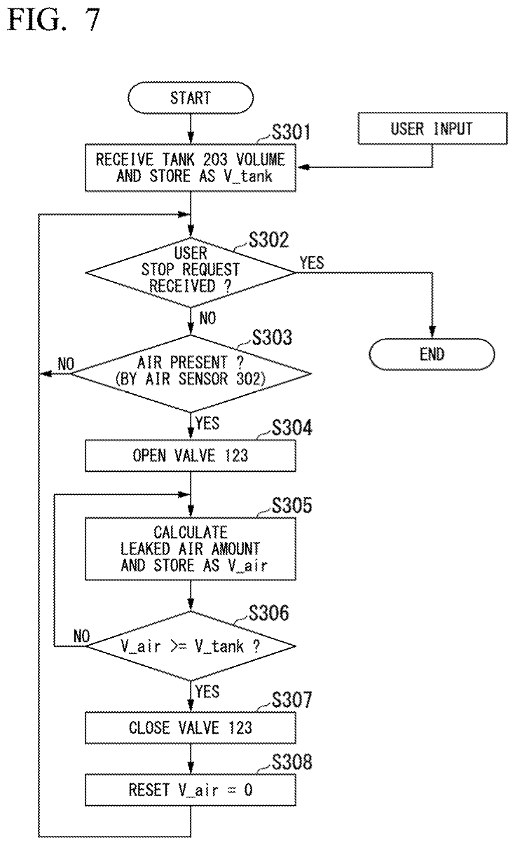

In another of example embodiment, air removal system including the pipe extension 121, a tank 203 containing an air sensor 302 and a tank bottom air sensor 302, a valve 123 and a flow meter 305 installed on the exhaust pipe 206. The method for air removal system operation in this example embodiment is explained below according to the flow chart shown in FIG. 7 and related to the configuration illustrated in FIG. 3

In Step S301, the air cooling system receives the volume of the tank 203 as user input and the tank 203 volume as V_tank.

In Step S302, the air removal system determines if user a stop command has been received or not. If not, then the air removal system proceeds to S303, else the air removal system stops.

In Step S303, the air sensor 302 placed inside the tank 203 detects if any air is present inside the tank 203. If the air sensor 302 detects air, then the air removal system proceeds to S304, else the air sensor returns to Step S302.

The physical significance of the air detection by the sensor 302 comes from the fact that the density of air is smaller than the refrigerant vapor density. When the air enters the inside of the tank 203 from the pipe extension 121, the air moves to the top part of the tank 203. Therefore, air detection by the air sensor 302 signifies that the tank 203 is completely filled with air.

In Step S304, if air is detected by the air sensor 302, then the valve 123 opens to expel the air out of cooling system. When the valve 123 opens, due to a pressure difference between the condenser 114 and the outside environment, the air expels from cooling system to outside environment via the exhaust pipe 206.

In Step S305, the air removal system calculates the total volume of air expelled from the cooling system by utilizing flow meter 305 and stores the total volume of expelled air as V_air.

The total volume of air expelled by air removal system can be calculated by time integral of flow rate data given by flow meter 305.

In Step S306, the air removal system compares V_air and V_tank. If V_air<V_tank, then the air removal system returns to S305, else operation proceeds to S307.

In Step S307, the air removal system closes the valve 123.

In Step S308, air removal system resets V_air=0.

While the preferred example embodiments of the present invention have been described, it is to be understood that the present invention is not limited to the example embodiments above and that further modifications, replacements, and adjustments may be added without departing from the basic technical concept of the present invention.

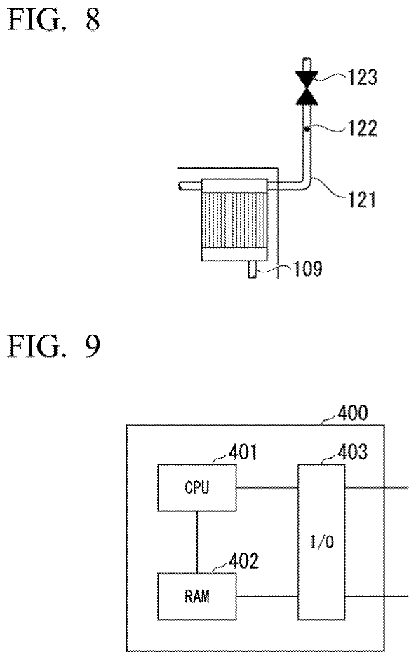

For example, the air removal methods of the above described example embodiments, may be implemented by a computer, a programmable logic device, or the like, having a basic structure shown in FIG. 8 such that a CPU 401 or similar processing unit is able to process instructions stored in RAM 402 and interact with components such as the air sensors 122, 204, 202, 302, the valve 123, and/or the flow meter 305 by way of an I/O unit 403.

Furthermore, the example embodiments may be implemented as an apparatus, a device, a method, or a computer program product. Accordingly, the present example embodiments may take the form of an entirely hardware embodiment, an entirely software embodiment (including firmware, resident software, micro-code, etc.), or an embodiment combining software and hardware aspects that may all generally be referred to herein as a “system.” Furthermore, aspects the present example embodiments may take the form of a computer program product embodied in any tangible medium of expression having computer-usable program code embodied in the medium.

### REFERENCE SIGNS

100 Air Removal System
101 Rack
102 Evaporator
103 Pipe
104 Compressor
105 Pipe
106 Heat Exchanger
109 Pipe
110 Tank
111 Pipe
112 Valve
113 Pipe
114 Condenser
121 Pipe
122 Air Sensor
123 Valve
201 Pipe
202 First Air Sensor
203 Tank
204 Second Air Sensor
206 Exhaust Pipe
302 Air Sensor
305 Flow Meter
400 Computer
401 CPU
402 RAM
403 I/O

What is claimed is:

1. An attachment for a server rack cooling system having at least one heat exchange condenser, the attachment comprising:
a pipe extension configured to connect to a portion of the server rack cooling system at which air and refrigerant are able to be transferred into the attachment from the at least one heat exchange condenser;
a valve on the pipe extension configured to allow exhaust to the outside through the pipe extension at an open position and to block exhaust to the outside at a closed position; and
a sensor disposed at a position inside of the pipe extension between the at least one heat exchange condenser and the valve and configured to provide a detection signal determined by a presence of fluid at the position of the sensor,
wherein, the valve is opened and closed based on the detection signal from the sensor.

2. The attachment of claim 1, wherein
the sensor is configured to detect one of the refrigerant and at least one of a component of atmospheric air.

3. The attachment of claim 2, wherein
the sensor is a plurality of sensors disposed at different positions along the pipe extension between the at least one heat exchange condenser and the valve, and
the valve is opened based on the detection signal of the furthest disposed sensor on one end of the pipe extension and closed based on the detection signal of the furthest disposed sensor on the other end of the pipe extension.

4. The attachment of claim 2, wherein
the valve is opened based on the detection signal of the sensor and closes after a predetermined amount of time.

5. The attachment of claim 2, further comprising:
a flow rate meter disposed inside of the pipe extension at a side of the valve opposite to the at least one heat exchange condenser and configured to measure a flow rate of fluid when the valve is open,
wherein the valve is closed based on an amount of fluid exhausted while the valve is open and a predetermined fluid capacity of the pipe extension between the position of the sensor and the valve.

6. The attachment of claim 1, further comprising:
a fluid tank disposed on the pipe extension between the heat exchange condenser and the valve and configured to store the fluid.

7. The attachment of claim 1, further comprising:
controller configured to receive at least the detection signal from the sensor and configured to control the valve.

8. An air removal method of an attachment for a cooling system having at least one heat exchange condenser, the air removal method comprising:
detecting a presence of a fluid at a position along an exhaust flow path of the attachment;
exhausting air from the attachment by opening a valve along the exhaust flow path based on the detection of the presence of the fluid; and
blocking the exhaust of air by closing the valve in absence of the detection of the presence of the fluid.

9. (canceled)

10. A server rack cooling system comprising:
a server rack;
an evaporator configured to remove heat generated by the server rack by way of a refrigerant flown through the evaporator and configured to maintain a lower pressure than the outside air pressure;
at least one heat exchange condenser configured to cool the refrigerant and into which refrigerant from the evaporator is flown;
a pipe extension which connects to the at least one heat exchange condenser;
a valve on the pipe extension configured to allow exhaust to the outside through the pipe extension at an open position and to block exhaust to the outside at a closed position; and
a sensor disposed at a position inside of the pipe extension between the at least one heat exchange condenser and the valve and configured to provide a detection signal determined by a presence of fluid at the position of the sensor,
wherein, the valve is opened and closed based on the detection signal from the sensor.

11. The server rack cooling system of claim 10, wherein
the evaporator is disposed up to 300 cm from the server rack.
